(19) United States
(12) Patent Application Publication
(10) Pub. No.: US 2025/0277138 A1
(43) Pub. Date: Sep. 4, 2025

(54) LAYER-ADDING ADHESIVE FILM CONTAINING MODIFIED BENZOCYCLOBUTENE FOR FC-BGA PACKAGE CARRIER, PREPARATION METHOD, AND APPLICATION THEREOF

(71) Applicant: SHENZHEN NEWCCESS INDUSTRIAL CO., LTD., Shenzhen (CN)

(72) Inventors: Lunqiang ZHANG, Shenzhen (CN); Di YANG, Shenzhen (CN); Hongxi HUANG, Shenzhen (CN); Xianzhi QIN, Shenzhen (CN); Gui YANG, Shenzhen (CN); Hua LIAO, Shenzhen (CN); Hailong WANG, Shenzhen (CN); Wanlu QIU, Shenzhen (CN); Zicong PENG, Shenzhen (CN)

(73) Assignee: SHENZHEN NEWCCESS INDUSTRIAL CO., LTD., Shenzhen (CN)

(21) Appl. No.: 18/883,545

(22) Filed: Sep. 12, 2024

(30) Foreign Application Priority Data
Feb. 29, 2024 (CN) 202410228053.2

(51) Int. Cl. C09J 5/04; C09J 7/25; C09J 11/04; C09J 11/06; C09J 163/00

(52) U.S. Cl. CPC C09J 5/04; C09J 7/255; C09J 11/04; C09J 11/06; C09J 163/00; C09J 2203/326; C09J 2301/408; C09J 2463/00; C09J 2467/00

(57) ABSTRACT

A layer-adding adhesive film containing modified benzocyclobutene for FC-BGA package carrier, a preparation method, and an application are provided. The layer-adding adhesive film includes the following components by weight: 45˜100 parts of epoxy resin, 40˜100 parts of inorganic filler, 25˜45 parts of cyanate ester, 40˜60 parts of modified benzocyclobutene, 5˜10 parts of acrylic resin, 5˜10 parts of phenoxy resin, 0.1˜1 part of curing accelerator, and 200˜300 parts of organic solvent; and the modified benzocyclobutene is one or two of nitric benzocyclobutene and phosphorated benzocyclobutene. The embodiments are based on components of epoxy resin, phenoxy resin, cyanate, curing accelerator, etc., by adding the modified benzocyclobutene for performance control, the layer-adding adhesive film have excellent permittivity, reduce dielectric dissipation, and have good flame retardant performance at the same time, which is better applied to FC-BGA package carrier.

### CROSS-REFERENCE TO RELATED APPLICATIONS

This application claims priority to Chinese Patent Application No. 202410228053.2, filed on Feb. 29, 2024, the content of all of which is incorporated herein by reference.

### FIELD

The present disclosure relates to the technical field of resin composite materials, in particular to a layer-adding adhesive film containing modified benzocyclobutene for FC-BGA package carrier, a preparation method and an application thereof.

### BACKGROUND

Flip-chip Ball Grid Array (FC-BGA) substrate is a high-density package carrier that can realize high-speed and multi-function of chips. With the increase of wiring density of Very Large Scale Integration Circuits (VLSI), the resistance of metal interconnection wires in electronic components and the capacitance of interlayer dielectric can easily form Resistance-Capacitance (RC) delay effect, which further causes adverse effects such as signal transmission delay and power loss.

A layer-adding adhesive film is one of the key core materials in semi-additive process (SAP) of FC-BGA package carrier, but the lack of dielectric properties of the layer-adding adhesive film material seriously affects its application in integrated circuits. In addition, the main component of the layer-adding adhesive film is polymer materials, which are flammable materials, and a large amount of smoke and toxic gases are released during combustion. Improving the flame retardant performance of the polymer materials has also become the key direction to overcome in layer-adding adhesive films.

Therefore, the existing technology needs to be improved and developed.

### SUMMARY

In view of the shortcomings of the prior art, a purpose of the present disclosure is to provide a layer-adding adhesive film containing modified benzocyclobutene for FC-BGA package carrier, a preparation method, and application thereof, aiming to solve the problem that the dielectric properties and flame retardant performance of the existing layer-adding adhesive film can not meet the requirements.

To solve the shortcomings, technical schemes of the present disclosure are as follows.

In a first aspect, the present disclosure provides a layer-adding adhesive film containing modified benzocyclobutene for FC-BGA package carrier, which includes following components in parts by weight:
45˜100 parts of epoxy resin, 40˜100 parts of inorganic filler, 25˜45 parts of cyanate ester, 40˜60 parts of modified benzocyclobutene, 5˜10 parts of acrylic resin, 5˜10 parts of phenoxy resin, 0.1˜1 part of curing accelerator, and 200˜300 parts of organic solvent;
the modified benzocyclobutene is one or two of nitric benzocyclobutene and phosphorated benzocyclobutene.

Optionally, the phosphorated benzocyclobutene is any one or at least two of I-type phosphorated benzocyclobutene, II-type phosphorated benzocyclobutene, and III-type phosphorated benzocyclobutene;

A structural formula of the I-type phosphorated benzocyclobutene is:

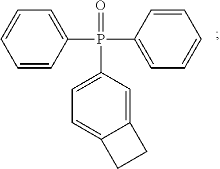 [SMILES: O=P(c1ccccc1)(c1ccccc1)c1ccc2c(c1)CC2]

a structural formula of the II-type phosphorated benzocyclobutene is:

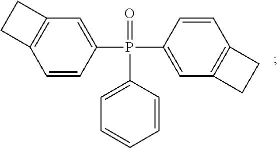 [SMILES: O=P(c1ccccc1)(c1ccc2c(c1)CC2)c1ccc2c(c1)CC2]

a structural formula of the III-type phosphorated benzocyclobutene is:

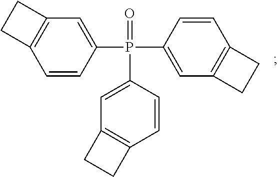 [SMILES: O=P(c1ccc2c(c1)CC2)(c1ccc2c(c1)CC2)c1ccc2c(c1)CC2]

Optionally, the nitric benzocyclobutene is selected from any one or at least two of I-type nitric benzocyclobutene, II-type nitric benzocyclobutene, and III-type nitric benzocyclobutene;
a structural formula of the I-type nitric benzocyclobutene is:

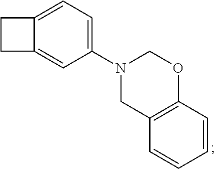 [SMILES: c1ccc2c(c1)CN(c1ccc3c(c1)CC3)CO2]

a structural formula of the II-type nitric benzocyclobutene is:

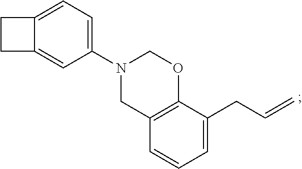 [SMILES: C=CCc1cccc2c1OCN(c1ccc3c(c1)CC3)C2]

a structural formula of the III-type nitric benzocyclobutene is:

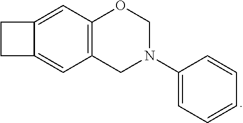 [SMILES: c1ccc(N2COc3cc4c(cc3C2)CC4)cc1]

Optionally, the epoxy resin is any one or at least two of bisphenol epoxy resin, biphenyl epoxy resin, naphthalene epoxy resin, naphthol epoxy resin, linear phenolic epoxy resin, dicyclopentadiene epoxy resin, aralkyl phenolic aldehyde epoxy resin, aralkyl biphenyl phenolic aldehyde epoxy resin, and naphthol phenolic epoxy resin.

Optionally, the inorganic filler is any one or at least two of silica, alumina, glass, cordierite, barium sulfate, barium carbonate, talc, clay, mica powder, zinc oxide, hydrotalcite, boehmite, aluminum hydroxide, magnesium hydroxide, calcium carbonate, magnesium carbonate, magnesium oxide, boron nitride, aluminum nitride, manganese nitride, aluminum borate, strontium carbonate, strontium titanate, calcium titanate, magnesium titanate, bismuth titanate, titanium oxide, zirconium oxide, barium titanate, barium zirconate, calcium zirconate, and zirconium phosphate.

Optionally, the curing accelerator is any one or at least two of 1-cyanoethyl-2-ethyl-4-methylimidazole, 2-phenyl-4,5-dimethylolimidazole, 2-phenyl-4-methyl-5-hydroxymethylimidazole, 2-ethyl-4-methylimidazole, 4-dimethylaminopyridine, and 2-phenylimidazole.

Optionally, the organic solvent is any one or at least two of toluene, xylene, butanone, methyl ethyl ketone, cyclohexanone, ethyl acetate, and N, N-dimethylformamide.

Optionally, the layer-adding adhesive film containing modified benzocyclobutene for FC-BGA package carrier further includes 3˜9 parts of additional additive;
the additional additive is any one or at least two of thickener, defoamer, homogenizer, leveling agent, adhesion-imparting agent, and colorant.

In a second aspect, the present disclosure further provides a method for preparing the layer-adding adhesive film containing modified benzocyclobutene for FC-BGA package carrier, the method includes:
uniformly mixing the components of the layer-adding adhesive film, coating on a substrate, and drying to obtain the layer-adding adhesive film;
a drying temperature is 80˜130° C., a drying time is 3˜10 min.

In a third aspect, the present disclosure further provides an application of the layer-adding adhesive film containing modified benzocyclobutene for FC-BGA package carrier in FC-BGA package carrier.

### Beneficial Effects

The present disclosure provides a layer-adding adhesive film containing modified benzocyclobutene for FC-BGA package carrier, a preparation method, and an application thereof. Based on components of epoxy resin, phenoxy resin, cyanate, curing accelerator, etc., the present disclosure adds the modified benzocyclobutene for performance control. By adding different types of modified benzocyclobutene, combined with other raw material components, the layer-adding adhesive film is made to have excellent permittivity, reduced dielectric dissipation, and good flame retardant performance at the same time, which is better applied to FC-BGA package carrier, so as to meet the requirements of high-speed and high-integration development of electronic components.

### DETAILED DESCRIPTION OF EMBODIMENTS

The present disclosure provides a layer-adding adhesive film containing modified benzocyclobutene for FC-BGA package carrier, a preparation method, and an application thereof. In order to make the purposes, technical schemes, and effects of the present disclosure more clear and definite, the present disclosure is further described in detail below. It should be understood that the specific embodiments described herein are only used to explain the present disclosure, not to limit the present disclosure.

One embodiment of the present disclosure provides a layer-adding adhesive film containing modified benzocyclobutene for FC-BGA package carrier including following components in parts by weight:
45˜100 parts of epoxy resin, 40˜100 parts of inorganic filler, 25˜45 parts of cyanate ester, 40˜60 parts of modified benzocyclobutene, 5˜10 parts of acrylic resin, 5˜10 parts of phenoxy resin, 0.1˜1 part of curing accelerator, and 200˜300 parts of organic solvent;
the modified benzocyclobutene is one or two of nitric benzocyclobutene and phosphorated benzocyclobutene.

According to the embodiment of the present disclosure, the dielectric performance is improved by using the modified benzocyclobutene. Specifically, the phosphorated benzocyclobutene can not release any small molecules in a process of ring opening, and its intramolecular polarity is low, which makes a cured resin of phosphorated benzocyclobutene have low dielectric properties. Functional groups such as benzene ring and heterocyclic ring of the nitric benzocyclobutene have low chemical bond polarizability, and the large-volume structure contained in the functional groups can increase free volume of the polymer. Using the nitric benzocyclobutene, low-polarity large-volume rigid functional groups can be introduced into the layer-adding adhesive film, thus reducing the permittivity and dielectric dissipation.

In another aspect, in the embodiment of the invention, the permittivity and the dielectric dissipation factor of the layer-adding adhesive film are reduced by using the modified benzocyclobutene (nitric benzocyclobutene and phosphorated benzocyclobutene) in combination, and a four-membered ring of the phosphorated benzocyclobutene and the nitric benzocyclobutene have an open-loop crosslinking reaction during a high-temperature curing process, so that between the phosphorated benzocyclobutene and the nitric benzocyclobutene, a network interconnection structure is formed by forming cyclic compounds, thereby reducing molecular polarization and improving dielectric properties.

Further, during the process of high-temperature curing, a phosphorus-nitrogen flame retardant system is formed by the ring-opening crosslinking reaction between the nitric benzocyclobutene and the phosphorated benzocyclobutene. Phosphorus can form a stable phosphorated carbon layer in condensed phase flame retardant, and nitrogen can generate non-toxic flame retardant gas at high temperature, which can dilute a concentration of combustible gas. At the same time, phosphorus and nitrogen cooperate to form a foamed porous expanded carbon layer, which can prevent combustible gas from entering the gas phase to achieve the functions of heat insulation and oxygen isolation, thus improving the flame retardant performance of the layer-adding adhesive film.

In some embodiments, a thickness of the layer-adding adhesive film is 10˜100 μm.

In some embodiments, the weight parts of the epoxy resin can be one of 45 parts, 50 parts, 55 parts, 60 parts, 65 parts, 70 parts, 75 parts, 80 parts, 85 parts, 90 parts, 95 parts, and 100 parts.

The weight parts of the inorganic filler can be one of 40 parts, 45 parts, 50 parts, 55 parts, 60 parts, 65 parts, 70 parts, 75 parts, 80 parts, 85 parts, 90 parts, 95 parts, and 100 parts.

The weight parts of the cyanate ester can be one of 25 parts, 30 parts, 35 parts, 40 parts, and 45 parts.

The weight parts of the modified benzocyclobutene can be one of 40 parts, 45 parts, 50 parts, 55 parts, and 60 parts.

The weight parts of the acrylic resin can be one of 5 parts, 6 parts, 7 parts, 8 parts, 9 parts, and 10 parts.

The weight parts of the phenoxy resin can be one of 5 parts, 6 parts, 7 parts, 8 parts, 9 parts, and 10 parts.

The weight parts of the curing accelerator can be one of 0.1 part, 0.2 part, 0.3 part, 0.4 part, 0.5 part, 0.6 part, 0.7 part, 0.8 part, 0.9 part, and 1 part.

The weight parts of the organic solvent can be one of 200 parts, 210 parts, 220 parts, 230 parts, 240 parts, 250 parts, 260 parts, 270 parts, 280 parts, 290 parts, and 300 parts.

In some embodiments, the phosphorated benzocyclobutene is selected from any one or at least two of I-type phosphorated benzocyclobutene, II-type phosphorated benzocyclobutene, and III-type phosphorated benzocyclobutene.

A structural formula of the I-type phosphorated benzocyclobutene is:

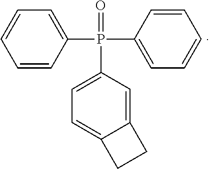 [SMILES: O=P(c1ccccc1)(c1ccccc1)c1ccc2c(c1)CC2]

A structural formula of the II-type phosphorated benzocyclobutene is:

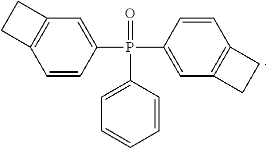 [SMILES: O=P(c1ccccc1)(c1ccc2c(c1)CC2)c1ccc2c(c1)CC2]

A structural formula of the III-type phosphorated benzocyclobutene is:

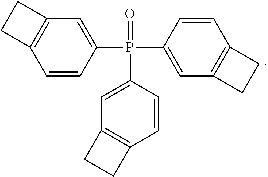 [SMILES: O=P(c1ccc2c(c1)CC2)(c1ccc2c(c1)CC2)c1ccc2c(c1)CC2]

Specifically, the phosphorated benzocyclobutene can not release any small molecules in a process of ring opening, and its intramolecular polarity is low, which makes a cured resin of phosphorated benzocyclobutene have low dielectric properties.

In some embodiments, the nitric benzocyclobutene is selected from any one or at least two of I-type nitric benzocyclobutene, II-type nitric benzocyclobutene, and III-type nitric benzocyclobutene.

A structural formula of the I-type nitric benzocyclobutene is:

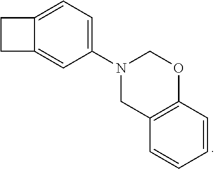 [SMILES: c1ccc2c(c1)CN(c1ccc3c(c1)CC3)CO2]

A structural formula of the II-type nitric benzocyclobutene is:

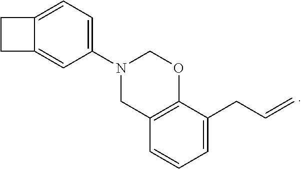 [SMILES: C=CCc1cccc2c1OCN(c1ccc3c(c1)CC3)C2]

A structural formula of the III-type nitric benzocyclobutene is:

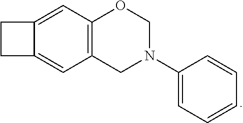 [SMILES: c1ccc(N2COc3cc4c(cc3C2)CC4)cc1]

Functional groups such as benzene ring and heterocyclic ring of the nitric benzocyclobutene have low chemical bond polarizability, and the large-volume structure contained in the functional groups can increase free volume of the polymer. By using the nitric benzocyclobutene, low-polarity large-volume rigid functional groups can be introduced into the layer-adding adhesive film, thus reducing the permittivity and dielectric dissipation.

In some embodiments, the epoxy resin is selected from any one or at least two of bisphenol epoxy resin, biphenyl epoxy resin, naphthalene epoxy resin, naphthol epoxy resin, linear phenolic epoxy resin, dicyclopentadiene epoxy resin, aralkyl phenolic aldehyde epoxy resin, aralkyl biphenyl phenolic aldehyde epoxy resin, and naphthol phenolic epoxy resin.

In some embodiments, the inorganic filler is selected from any one or at least two of silica, alumina, glass, cordierite, barium sulfate, barium carbonate, talc, clay, mica powder, zinc oxide, hydrotalcite, boehmite, aluminum hydroxide, magnesium hydroxide, calcium carbonate, magnesium carbonate, magnesium oxide, boron nitride, aluminum nitride, manganese nitride, aluminum borate, strontium carbonate, strontium titanate, calcium titanate, magnesium titanate, bismuth titanate, titanium oxide, zirconium oxide, barium titanate, barium zirconate, calcium zirconate, and zirconium phosphate.

In some embodiments, the acrylic resin is XX-5598Z type of SEKISUI CHEMICAL CO., LTD.

In some embodiments, the phenoxy resin is selected from any one or at least two of FX280 type of NIPPON STEEL CO., FX293 type of NIPPON STEEL Co., YX8100 type of MITSUBISHI CHEMICAL GROUP CO., YX7553BH30 type of MITSUBISHI CHEMICAL GROUP CO., YX7200B35 type of MITSUBISHI CHEMICAL GROUP CO., and TER240C30 type of TONGYU ADVANCED MATERIALS (GUANGDONG) CO. LTD.

In some embodiments, the curing accelerator is selected from any one or at least two of 1-cyanoethyl-2-ethyl-4-methylimidazole, 2-phenyl-4,5-dimethylolimidazole, 2-phenyl-4-methyl-5-hydroxymethylimidazole, 2-ethyl-4-methylimidazole, 4-dimethylaminopyridine, and 2-phenylimidazole.

In some embodiments, the organic solvent is selected from any one or at least two of toluene, xylene, butanone, methyl ethyl ketone, cyclohexanone, ethyl acetate, and N, N-dimethylformamide.

In some embodiments, the layer-adding adhesive film further includes 3˜9 parts of additional additive.

The additional additive is selected from any one or at least two of thickener, defoamer, homogenizer, leveling agent, adhesion-imparting agent, and colorant.

In some embodiments, the present disclosure further provides a method for preparing a layer-adding adhesive film containing modified benzocyclobutene for FC-BGA package carrier, and the method includes:
uniformly mixing the components of the layer-adding adhesive film, coating on a substrate, and drying to obtain the laminating adhesive film.

A drying temperature is 80˜130° C., a drying time is 3˜10 min.

In some embodiments, a thickness of the FC-BGA package carrier is 10˜150 μm. The thickness can be 10 μm, 20 μm, 30 μm, 40 μm, 50 μm, 60 μm, 70 μm, 80 μm, 90 μm, 100 μm, 110 μm, 120 μm, 130 μm, 140 μm, 150 μm.

It should be noted that the embodiments of the present disclosure have no special limitation on the selection of the substrate, and all substrates commonly used in the field can be used, including but not limited to PET release film, polyethylene film, polypropylene film or polyvinyl chloride film. At the same time, in order to facilitate the subsequent removal of the substrate, the polyethylene film, polypropylene film, or polyvinyl chloride film can be corona-treated in advance before use.

In some embodiments, the drying temperature can be 80° C., 90° C., 100° C., 110° C., 120° C., 130° C.

The drying time can be 3 min, 4 min, 5 min, 6 min, 7 min, 8 min, 9 min, or 10 min.

In some embodiments, after drying the method further includes a post-treatment step; the post-treatment method is removing the base material.

In some embodiments, the present disclosure further provides an application of the layer-adding adhesive film containing modified benzocyclobutene for FC-BGA package carrier in FC-BGA package carrier.

The technical schemes in the embodiment of the present disclosure are described clearly and completely below. Obviously, the described embodiments are only a part of the embodiments of the present disclosure, not all the embodiments, and it is only for illustrating the present disclosure without limiting it in any way. Based on the embodiments in the present disclosure, all other embodiments obtained by those skilled in the art with no inventive labor belong to the scope of protection of the present disclosure.

The raw materials in the examples and comparative examples of the present disclosure are as follows:

Epoxy resin: biphenyl epoxy resin (NC-3000-L type of NIPPON KAYAKU BUSINESS STYLE), phenol epoxy resin (WHR-991S type of NIPPON KAYAKU BUSINESS STSLE), bisphenol A-type epoxy resin (jER828EL type of MITSUBISHI CHEMICAL GROUP CO.), naphthalene epoxy resin (HP-6000 type of DIC Co.)
Inorganic filler: spherical silica (SOC2 type of ADMATECHS CO. LTD.);
Cyanate ester: cyanate ester (BA230S75 type of LONZA JAPAN CO.);
Acrylic resin: acrylic resin (XX-5598Z type of SEKISUI CHEMICAL CO., LTD.);
Phenoxy resin: phenoxy resin (YX7553BH30 type of MITSUBISHI CHEMICAL GROUP CO.).

### Embodiment 1

A layer-adding adhesive film containing modified benzocyclobutene for FC-BGA package carrier is provided in Embodiment 1, and in parts by weight, the raw materials of the layer-adding adhesive film includes:

30 parts of biphenyl epoxy resin (NC-3000-L), 5 parts of phenol epoxy resin (WHR-991s), 10 parts of bisphenol A-type liquid epoxy resin (jER828EL), 100 parts of spherical silica (SOC2), 45 parts of cyanate ester (BA230s), 60 parts of phosphorus-containing benzocyclobutene, 10 parts of acrylic resin (XX-5598Z), 5 parts of phenoxy resin (YX7553BH30), 0.1 part of 4-dimethylaminopyridine (DMAP), and 300 parts of cyclohexanone.

A method for preparing the layer-adding adhesive film included: the raw material components were uniformly mixed according to the above ratio, and then coated on the PET release film. After drying at 80° C. for 10 min, the PET release film was removed, and the layer-adding adhesive film with a thickness of 100 μm was obtained.

### Embodiment 2

A layer-adding adhesive film containing modified benzocyclobutene for FC-BGA package carrier is provided in Embodiment 2, and in parts by weight, the raw materials of the layer-adding adhesive film include:

30 parts of biphenyl epoxy resin (NC-3000-L), 5 parts of phenol epoxy resin (WHR-991s), 10 parts of bisphenol A-type liquid epoxy resin (jER828EL), 100 parts of spherical silicon dioxide (SOC2), 45 parts of cyanate ester (Ba230s), 60 parts of nitric benzocyclobutene, 10 parts of acrylic resin (XX-5598Z), 5 parts of phenoxy resin (YX7553BH30), 0.1 part of 4-dimethylaminopyridine (DMAP), and 300 parts of cyclohexanone.

A method for preparing the layer-adding adhesive film included: the raw material components were uniformly mixed according to the above ratio, and then coated on the PET release film. After drying at 130° C. for 3 min, the PET release film was removed, and the layer-adding adhesive film with a thickness of 100 μm was obtained.

### Embodiment 3

A layer-adding adhesive film containing modified benzocyclobutene for FC-BGA package carrier is provided in Embodiment 3, and in parts by weight, the raw materials of the layer-adding adhesive film include:

30 parts of biphenyl epoxy resin (NC-3000-L), 5 parts of phenol epoxy resin (WHR-991s), 10 parts of bisphenol A-type liquid epoxy resin (jER828EL), 100 parts of spherical silica (SOC2), 25 parts of cyanate ester (BA230S75), 30 parts of phosphorated benzocyclobutene, 30 parts of nitric benzocyclobutene, 10 parts of acrylic resin (XX-5598Z), 5 parts of phenoxy resin (YX7553BH30), 0.1 part of 4-dimethylaminopyridine (DMAP), and 300 parts of cyclohexanone.

A method for preparing the layer-adding adhesive film included: the raw material components were uniformly mixed according to the above ratio, and then coated on the PET release film. After drying at 110° C. for 5 min, the PET release film was removed, and the layer-adding adhesive film with a thickness of 40 μm was obtained.

### Embodiment 4

A layer-adding adhesive film containing modified benzocyclobutene for FC-BGA package carrier is provided in Embodiment 4, and in parts by weight, the raw materials of the layer-adding adhesive film include:

100 parts of naphthalene epoxy resin (HP-6000), 40 parts of spherical silica (SOC2), 45 parts of cyanate ester (BA230S75), 40 parts of phosphorated benzocyclobutene, 5 parts of acrylic resin (XX-5598Z), 5 parts of phenoxy resin (YX7553BH30), 1 part of 2-ethyl-4-methyl glyoxaline (2E4 MI), and 200 parts of butanone.

A method for preparing the layer-adding adhesive film included: the raw material components were uniformly mixed according to the above ratio, and then coated on the PET release film. After drying at 80° C. for 10 min, the PET release film was removed, and the layer-adding adhesive film with a thickness of 100 μm was obtained.

### Embodiment 5

A layer-adding adhesive film containing modified benzocyclobutene for FC-BGA package carrier is provided in Embodiment 5, and in parts by weight, the raw materials of the layer-adding adhesive film include:

80 parts of naphthalene epoxy resin (HP-6000), 60 parts of spherical silica (SOC2), 30 parts of cyanate ester (BA230S75), 50 parts of phosphorated benzocyclobutene, 5 parts of acrylic resin (XX-5598Z), 5 parts of phenoxy resin (YX7553BH30), 0.5 part of 2-ethyl-4-methyl glyoxaline (2E4 MI), and 250 parts of butanone.

A method for preparing the layer-adding adhesive film included: the raw material components were uniformly mixed according to the above ratio, and then coated on the PET release film. After drying at 80° C. for 10 min, the PET release film was removed, and the layer-adding adhesive film with a thickness of 100 μm was obtained.

### Embodiment 6

A layer-adding adhesive film containing modified benzocyclobutene for FC-BGA package carrier is provided in Embodiment 6, and in parts by weight, the raw materials of the layer-adding adhesive film include:

100 parts of naphthalene epoxy resin (HP-6000), 40 parts of spherical silica (SOC2), 45 parts of cyanate ester (BA230S75), 25 parts of phosphorated benzocyclobutene, 25 parts of nithic benzocyclobutene, 5 parts of acrylic resin (XX-5598Z), 5 parts of phenoxy resin (YX7553BH30), 1 part of 2-ethyl-4-methyl glyoxaline (2E4 MI), and 200 parts of butanone.

A method for preparing the layer-adding adhesive film included: the raw material components were uniformly mixed according to the above ratio, and then coated on the PET release film. After drying at 80° C. for 10 min, the PET release film was removed, and the layer-adding adhesive film with a thickness of 100 μm was obtained.

### Comparative Example 1

A layer-adding adhesive film is provided, and in parts by weight, the raw materials of the layer-adding adhesive film include:

30 parts of biphenyl epoxy resin (NC-3000-L), 5 parts of phenol epoxy resin (WHR-991s), 10 parts of bisphenol A-type liquid epoxy resin (jER828EL), 100 parts of spherical silica (SOC2), 25 parts of cyanate ester (BA230S75), 10 parts of acrylic resin (XX-5598Z), 5 parts of phenoxy resin (YX7553BH30), 0.1 part of 4-dimethylaminopyridine (DMAP), and 300 parts of cyclohexanone.

A method for preparing the layer-adding adhesive film included: the raw material components were uniformly mixed according to the above ratio, and then coated on the PET release film. After drying at 80° C. for 10 min, the PET release film was removed, and the layer-adding adhesive film with a thickness of 100 μm was obtained.

The properties of the layer-adding adhesive films provided in the above examples and comparative examples were tested by the following methods:

The permittivity and the dielectric dissipation factor: the layer-adding adhesives with PET release film provided in the above examples and comparative examples were solidified at 180° C. for 30 min, and the release film was peeled off, thereby obtaining a pre-solidified layer-adding adhesive film; The pre-solidified layer-adding adhesive film was cut into 2 mm×80 mm test pieces (3 pieces), and then the permittivity and dielectric dissipation factor of each test piece were measured by using “HP8362B” of Agilent Technology Co., Ltd. under conditions of measuring frequency of 5.8 GHZ and measuring temperature of 23° C., and an average of the permittivity and dielectric dissipation factor of the three test pieces was found to be the permittivity and the dielectric dissipation factor.

Flame retardant performance: the layer-adding adhesive films with PET release film provided in the above examples and comparative examples and a substrate (MCL-E-705G of Hitachi Chemical Corporation, Japan) were pressed by a laminator, and the layer-adding adhesive films (the side without PET release film) were respectively pressed on both sides of the substrate to obtain a laminated body; After the lamination, the PET release film on the laminated body was removed, and the layer-adding adhesive film was thermally solidified (at 190° C. for 90 min) to form solidified products on both sides of the substrate. The laminated body (about 380 μm in thickness) was cut into samples with a size of 12.7 mm×127 mm and an edge of 1.27 mm, and tested according to UL-94V standard, and the test results were recorded.

The performance test results of the layer-adding adhesive films provided by examples and comparative examples are shown in Table 1.

TABLE 1

| | | Dielectric | |
|---|---|---|---|
| | | Dissipation Factor | Flame Retardance |
| | Permittivity | (tanδ) | (UL-94V) |
| Example 1 | 2.9 | 0.0037 | V-1 |
| Example 2 | 2.9 | 0.0038 | V-1 |
| Example 3 | 2.7 | 0.0032 | V-0 |
| Example 4 | 3.0 | 0.0039 | V-1 |
| Example 5 | 2.9 | 0.0038 | V-1 |
| Example 6 | 2.7 | 0.0033 | V-0 |
| Comparative | 3.2 | 0.0044 | V-1 |
| Example 1 | | | |

It should be understood that the application of the present disclosure is not limited to the above embodiments, and those skilled in the art can make improvements or transformations according to the above descriptions, and all these improvements and transformations should belong to the protection scope of the appended claims of the present disclosure.

What is claimed is:

1. A layer-adding adhesive film containing modified benzocyclobutene for FC-BGA package carrier, the layer-adding adhesive film comprising following components in parts by weight:
45˜100 parts of epoxy resin, 40˜100 parts of inorganic filler, 25˜45 parts of cyanate ester, 40˜60 parts of modified benzocyclobutene, 5˜10 parts of acrylic resin, 5˜10 parts of phenoxy resin, 0.1˜1 part of curing accelerator, and 200˜300 parts of organic solvent;
wherein the modified benzocyclobutene is at least one of nitric benzocyclobutene and phosphorated benzocyclobutene.

2. The layer-adding adhesive film containing modified benzocyclobutene for FC-BGA package carrier of claim 1, wherein the phosphorated benzocyclobutene is selected from the group consisting of: I-type phosphorated benzocyclobutene, II-type phosphorated benzocyclobutene, and III-type phosphorated benzocyclobutene;
wherein a structural formula of the I-type phosphorated benzocyclobutene is: 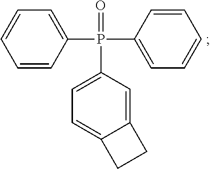 [SMILES: O=P(c1ccccc1)(c1ccccc1)c1ccc2c(c1)CC2]
wherein a structural formula of the II-type phosphorated benzocyclobutene is: 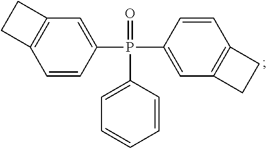 [SMILES: O=P(c1ccccc1)(c1ccc2c(c1)CC2)c1ccc2c(c1)CC2]
and
wherein a structural formula of the III-type phosphorated benzocyclobutene is:

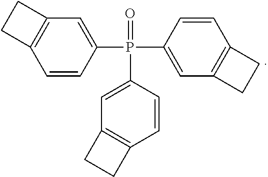 [SMILES: O=P(c1ccc2c(c1)CC2)(c1ccc2c(c1)CC2)c1ccc2c(c1)CC2]

3. The layer-adding adhesive film containing modified benzocyclobutene for FC-BGA package carrier of claim 1, wherein the nitric benzocyclobutene is selected from the group consisting of: I-type nitric benzocyclobutene, II-type nitric benzocyclobutene, and III-type nitric benzocyclobutene;
wherein a structural formula of the I-type nitric benzocyclobutene is: 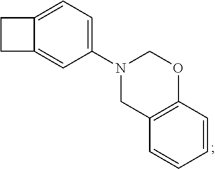 [SMILES: c1ccc2c(c1)CN(c1ccc3c(c1)CC3)CO2]
wherein a structural formula of the II-type nitric benzocyclobutene is: 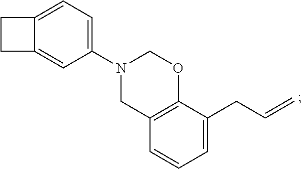 [SMILES: C=CCc1cccc2c1OCN(c1ccc3c(c1)CC3)C2]
and
wherein a structural formula of the III-type nitric benzocyclobutene is:

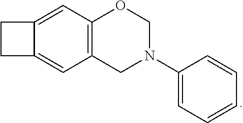 [SMILES: c1ccc(N2COc3cc4c(cc3C2)CC4)cc1]

4. The layer-adding adhesive film containing modified benzocyclobutene for FC-BGA package carrier of claim 1, wherein the epoxy resin is selected from the group consisting of: bisphenol epoxy resin, biphenyl epoxy resin, naphthalene epoxy resin, naphthol epoxy resin, linear phenolic epoxy resin, dicyclopentadiene epoxy resin, aralkyl phenolic aldehyde epoxy resin, aralkyl biphenyl phenolic aldehyde epoxy resin, and naphthol phenolic epoxy resin.

5. The layer-adding adhesive film containing modified benzocyclobutene for FC-BGA package carrier of claim 1, wherein the inorganic filler is selected from the group consisting of: silica, alumina, glass, cordierite, barium sulfate, barium carbonate, talc, clay, mica powder, zinc oxide, hydrotalcite, boehmite, aluminum hydroxide, magnesium hydroxide, calcium carbonate, magnesium carbonate, magnesium oxide, boron nitride, aluminum nitride, manganese nitride, aluminum borate, strontium carbonate, strontium titanate, calcium titanate, magnesium titanate, bismuth titanate, titanium oxide, zirconium oxide, barium titanate, barium zirconate, calcium zirconate, and zirconium phosphate.

6. The layer-adding adhesive film containing modified benzocyclobutene for FC-BGA package carrier of claim 1, wherein the curing accelerator is selected from the group consisting of: 1-cyanoethyl-2-ethyl-4-methylimidazole, 2-phenyl-4,5-dimethylolimidazole, 2-phenyl-4-methyl-5-hydroxymethylimidazole, 2-ethyl-4-methylimidazole, 4-dimethylaminopyridine, and 2-phenylimidazole.

7. The layer-adding adhesive film containing modified benzocyclobutene for FC-BGA package carrier of claim 1, wherein the organic solvent is selected from the group consisting of: toluene, xylene, butanone, methyl ethyl ketone, cyclohexanone, ethyl acetate, and N, N-dimethylformamide.

8. The layer-adding adhesive film containing modified benzocyclobutene for FC-BGA package carrier of claim 1, further comprising 3˜9 parts of additional additive; and
the additional additive is selected from the group consisting of: thickener, defoamer, homogenizer, leveling agent, adhesion-imparting agent, and colorant.

9. A method for preparing the layer-adding adhesive film containing modified benzocyclobutene for FC-BGA package carrier of claim 1, the method comprising:
uniformly mixing the components of the layer-adding adhesive film, coating on a substrate, and drying to obtain the laminating adhesive film.

10. An application of the layer-adding adhesive film containing modified benzocyclobutene for FC-BGA package carrier of claim 1 in FC-BGA package carrier.
